(19) United States
(12) Patent Application Publication
(10) Pub. No.: US 2025/0246247 A1
(43) Pub. Date: Jul. 31, 2025

(54) PROGRESSIVE READ-LEVEL OFFSETS FOR PARTIAL BLOCKS

(71) Applicant: Micron Technology, Inc., Boise, ID (US)

(72) Inventors: Zhongguang Xu, San Jose, CA (US); Jason H. Culp, Manassas, VA (US)

(21) Appl. No.: 19/039,455

(22) Filed: Jan. 28, 2025

Related U.S. Application Data
(60) Provisional application No. 63/626,458, filed on Jan. 29, 2024.

(51) Int. Cl. G11C 16/26; G11C 16/08; G11C 16/34

(52) U.S. Cl. CPC G11C 16/26; G11C 16/08; G11C 16/3418; G11C 2207/2254

(57) ABSTRACT

A command to read data stored in a block of a memory device is received. The block is determined to be a partial block based on the block having one or more unprogrammed pages. Based on the block being a partial block, a partial block offset table is accessed. The partial block offset table comprises a mapping between word line numbers and read-level voltage offsets for partial blocks. A last written page in the block is identified and a word line type is determined based on the last written page. A first read-level voltage offset for the block is determined from the partial block offset table based on the last written page and the word line type. The first read-level voltage offset is applied to the block before performing a read-level voltage calibration process that includes determining second read-level voltage offsets for the block.

### PRIORITY APPLICATION

This application claims the benefit of priority to U.S. Provisional Application Ser. No. 63/626,458, filed Jan. 29, 2024, which is incorporated herein by reference in its entirety.

### TECHNICAL FIELD

Embodiments of the disclosure relate generally to memory sub-systems and, more specifically, to techniques for applying progressive read-level offset for read operations on partial blocks in a memory device.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data at the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 illustrates an example computing environment that includes a memory sub-system, in accordance with some embodiments of the present disclosure.

FIG. 2 is a data flow diagram illustrating interactions between components in the memory sub-system in performing a method for applying read-level voltage offsets in partial blocks, in accordance with some embodiments of the present disclosure.

FIGS. 3A and 3B are flow diagrams illustrating an example method for performing a method for applying read-level voltage offsets in partial blocks, in accordance with some embodiments of the present disclosure.

FIG. 4 is a block diagram of an example computer system in which embodiments of the present disclosure may operate.

### DETAILED DESCRIPTION

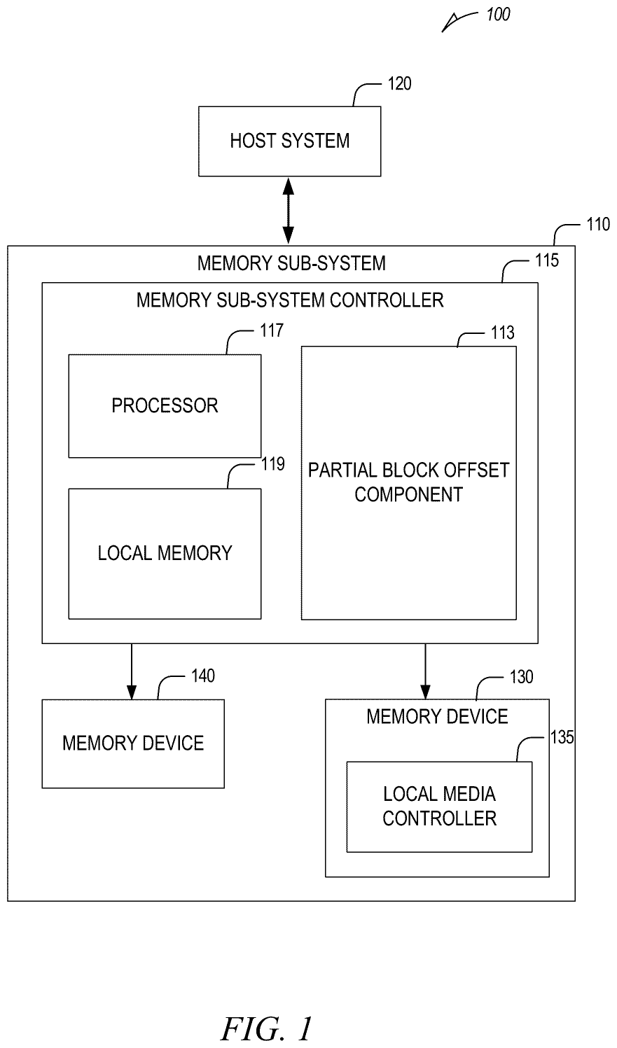

Aspects of the present disclosure are directed to an approach for applying read-level voltage offsets in partial blocks of a memory device of a memory sub-system. A memory sub-system can be a storage device (e.g., SSD), a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system. A memory sub-system controller typically receives commands or operations from the host system and converts the commands or operations into instructions or appropriate commands to achieve the desired access to the memory components of the memory sub-system.

A memory device can be a non-volatile memory device. One example of a non-volatile memory device is a negative-and (NAND) memory device. A NAND memory device can include multiple NAND dies. Each die may include one or more planes and each plane includes multiple blocks. Each block includes an array that includes pages (rows) and strings (columns). A string includes a plurality of memory cells connected in series. A memory cell (also referred to herein simply as a “cell”) is an electronic circuit that stores information. Depending on the cell type, a cell can store one or more bits of binary information and has various logic states that correlate to the number of bits being stored. The logic states can be represented by binary values, such as “0” and “1,” or combinations of such values.

Various memory access operations can be performed on the memory cells. Data can be written to, read from, and erased from memory cells. Memory cells can be grouped into a write unit, such as a page. For some types of memory devices, a page is the smallest write unit. Data can be written to a block, page-by-page. During write operations, data is programmed into a block of the memory device using a programming sequence that includes multiple passes in which programming pulses are applied to cells in the block. Over the multiple passes, the programming pulses configure the threshold voltages (Vt) of the cells in each page according to the value that the cells are intended to represent. As the programming sequence progresses, the voltage level of the programming pulses increase until a target voltage level for each cell is reached. A block in which all pages have been programmed is referred to herein as a “full block” while a block that has at least one programmed page and one unprogrammed page is referred to herein as a “partial block.”

The Vt distribution of a memory cell can be divided into a number of regions based on the number of bits stored by the cell where each region corresponds to a value that can be represented by the cell. More specifically, each region corresponds to a read level and each read level decodes into a multi-bit value. For example, a triple-level cell (TLC) NAND flash cell can be at one of eight charge levels (L0, L1, L2, L3, L4, L5, L6, or L7) and each charge level decodes into a 3-bit value that is stored in the flash cell (e.g., 111, 110, 100, 000, 010, 011, 001, and 101).

For memory devices such as a NAND memory device, Slow Charge Loss (SCL) of memory cells is a major degradation mechanism for data retention (DR). In particular, due to the effects of SCL, memory cells have their Vt distributions lose charge, with the highest Vt distributions typically losing charge faster than lower Vt distributions. SCL is usually a function of time and temperature, and can also be susceptible to other factors, such as cycling degradation (e.g., more Vt distribution shift for End of Life (EOL) blocks than for Beginning of Life (BOL) blocks). SCL usually causes a memory cell's Vt distribution to shift lower (e.g., causes the Vt distribution valley to shift lower) right after the memory cell is programmed.

Generally, to read data from a memory cell, one or more read-level voltages are applied to the gate of a transistor (of the memory cell) to determine (e.g., sense) the value of the current Vt (e.g., the voltage at which the transistor conducts current), and the current Vt value can be decoded (e.g., mapped) to a data value (e.g., bit string) stored by the memory cell. To compensate for a SCL-based shift when performing a read operation on a memory cell, an offset (or read-level voltage offset) is usually applied to one or more read level voltages (also referred to herein as read levels) used to read data from the memory cell.

Many calibration methods can be used individually and in combination to determine read-level voltage offsets. One such calibration method is digital count fail byte (DCFB) sensing. With the DCFB sensing, read-level voltage offsets are determined based on the number of failing bits detected at the highest programmed cell level during a test read operation.

DCFB sensing works by first performing a test read operation at the highest programmed cell level (typically level 7) using an initial default read-level voltage. During this test read, the number of failing bits is counted and compared to a predetermined total number of bits at that cell level. If too few bits fail the test read, it indicates the initial read-level voltage is too low and needs to shift higher. Specifically, the read-level voltage is calibrated to such that no more than a predetermined portion (e.g., ⅛th) of the total bits fail the test read. This would indicate the read-level voltage is centered on the edge of the cell level distribution. Conversely, if too many bits fail the test read, the initial read-level voltage is too high and needs to shift lower to get closer to the failure target. Once the optimal read-level voltage is determined for the highest cell level, DCFB sensing refers to preset tables to determine appropriate offsets for the lower cell levels. The read-level voltage offsets are calibrated to account for expected differences between cell levels due to charge loss over time and other effects.

For NAND memory devices, properly reading data from a partial block can be more challenging than a full block due to the differences in voltage threshold levels between cells in the partial block. The challenges associated with partial block reads can lead to increased error rates, which, if not properly managed, can compromise data integrity and reliability of the memory device.

As an example, within a NAND device, each cell's stored charge corresponds to a data value, which is read by applying a specific read-level voltage, as noted above. In a partial block, the cells at the boundary of the written and unwritten areas exhibit variability in their Vts due to less string resistance and a lack of cell-to-cell (C2C) coupling. This variability can lead to incorrect reads if the read-level voltage offsets calibrated for full blocks are used. As another example, in a full block, C2C coupling is consistent across the block, but in a partial block, the absence of programmed cells at the boundary reduces the coupling effect. This reduction can cause a shift in the read-level voltages of the boundary cells, making it more challenging to determine the correct read voltages. As yet another example, in a full block, all cells contribute to the overall string resistance, leading to a stable environment for reading data. However, in a partial block, the unwritten cells do not contribute in the same way, resulting in a different resistance profile and, consequently, a shift in the read-level voltages required for accurate reads. As still yet another example, SCL trends in partial blocks can differ significantly from SCL observed in full blocks, thereby necessitating additional offsets to compensate for these differences when reading partial blocks.

The forgoing examples of the differences between partial and full blocks lead to read errors for partial blocks, which are particularly problematic when read-level voltage offsets are calibrated based on the characteristics of fully written blocks (full blocks) such as with the DCFB sensing method discussed above. When read-level voltages are not accurately calibrated with offsets for partial blocks, it can lead to higher rates of read retries (also referred to as “trigger rates”). Each retry represents an attempt to re-read the data with adjusted read-level voltages, which can slow down the read process and reduce the overall performance of the memory device.

Aspects of the present disclosure address the above and other issues by utilizing a progressive compensation method for calibrating read-level voltages of partial blocks through application read-level voltage offsets that are specific to the conditions of partial blocks. In an example, a memory sub-system receives a command to read data stored in a block of a memory device. Based on receiving the read command, a partial block offset component determines whether the block is a partial block (e.g., a block with at least one programmed page and one or more unprogrammed pages). If the block is a partial block, the partial block offset component consults a partial block offset table that contains information on how to adjust the read-level voltages for different word lines within partial blocks, which is crucial for accurate data reading. The partial block offset component identifies the last written page (LWP) within the block and uses this information to determine a word line type. The partial block offset component selects a set of read-level voltage offsets from the table for the block based on one or more word line numbers associated with the LWP and the determined word line type. These offsets are then applied to the block (or more specifically to memory cells of the block) as part of a read-level voltage calibration process, (e.g., DFCB sensing) that involves determining a second set of read-level voltage offsets for the block based on the number of errors detected during an initial read. The second set of read-level voltage offsets are applied to the block when performing a read operation to read the requested data from the block, which is then provided by the memory sub-system responsive to the command.

Applying read-level voltage offsets for partial blocks in this manner ensures that read-level voltages are calibrated to the unique characteristics of partial blocks, thereby improving read accuracy and maintaining data integrity within the memory device.

FIG. 1 illustrates an example computing environment 100 that includes a memory sub-system 110, in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a SSD, a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, and so forth.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a USB interface, a Fibre Channel interface, a Serial Attached SCSI (SAS) interface, and so forth. The physical host interface can be used to transmit data between the host system 120 and the memory sub-system 110. The host system 120 can further utilize a Non-Volatile Memory Express (NVMe) interface to access the memory devices 130 and 140 when the memory sub-system 110 is coupled with the host system 120 by the PCIe or CXL interface. The physical host interface can provide an interface for passing control, address, data, and other signals between the memory sub-system 110 and the host system 120.

The memory devices can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

An example of non-volatile memory devices (e.g., memory device 130) includes a NAND type flash memory. Each of the memory devices 130 can include one or more arrays of memory cells such as SLCs, multi-level cells (MLCs) (e.g., TLCs, or quad-level cells (QLCs)). In some embodiments, a particular memory component can include an SLC portion, and an MLC portion, a TLC portion, or a QLC portion of memory cells. Each of the memory cells can store one or more bits of data used by the host system 120. Furthermore, the memory cells of the memory devices 130 can be grouped as memory pages or memory blocks that can refer to a unit of the memory component used to store data.

Although non-volatile memory components such as NAND type flash memory are described, the memory device 130 can be based on any other type of non-volatile memory, such as read-only memory (ROM), phase change memory (PCM), magneto random access memory (MRAM), NOR flash memory, electrically erasable programmable read-only memory (EEPROM), and a cross-point array of non-volatile memory cells. A cross-point array of non-volatile memory can perform bit storage based on a change of bulk resistance in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased.

A memory sub-system controller 115 can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, and the like. The local memory 119 can also include ROM for storing micro-code. While the example memory sub-system 110 in FIG. 1 has been illustrated as including the memory sub-system controller 115, in another embodiment of the present disclosure, a memory sub-system 110 may not include a memory sub-system controller 115, and may instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical block address and a physical block address that are associated with the memory devices 130. The memory sub-system controller 115 can further include host interface circuitry to communicate with the host system 120 via the physical host interface. The host interface circuitry can convert the commands received from the host system into command instructions to access the memory devices 130 and convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130.

The memory sub-system 110 also includes a partial block offset component 113 that is responsible for determining and applying read-level voltage offsets to partial memory blocks (e.g., blocks within the memory device 130 with at least one programmed page and at least one unprogrammed page). The partial block offset component 113 determines the read-level voltage offsets for partial blocks using a stored partial block offset table that maps word lines to read-level voltage offsets. Further details regarding the operation of the partial block offset component 113 are discussed below.

In some embodiments, the memory sub-system controller 115 includes at least a portion of the partial block offset component 113. For example, the memory sub-system controller 115 can include a processor 117 (processing device) configured to execute instructions stored in local memory 119 (e.g., firmware) for performing the operations described herein. In some embodiments, the Partial block offset component 113 is part of the host system 120, an application, or an operating system. Further details regarding the partial block offset component 113 are discussed below.

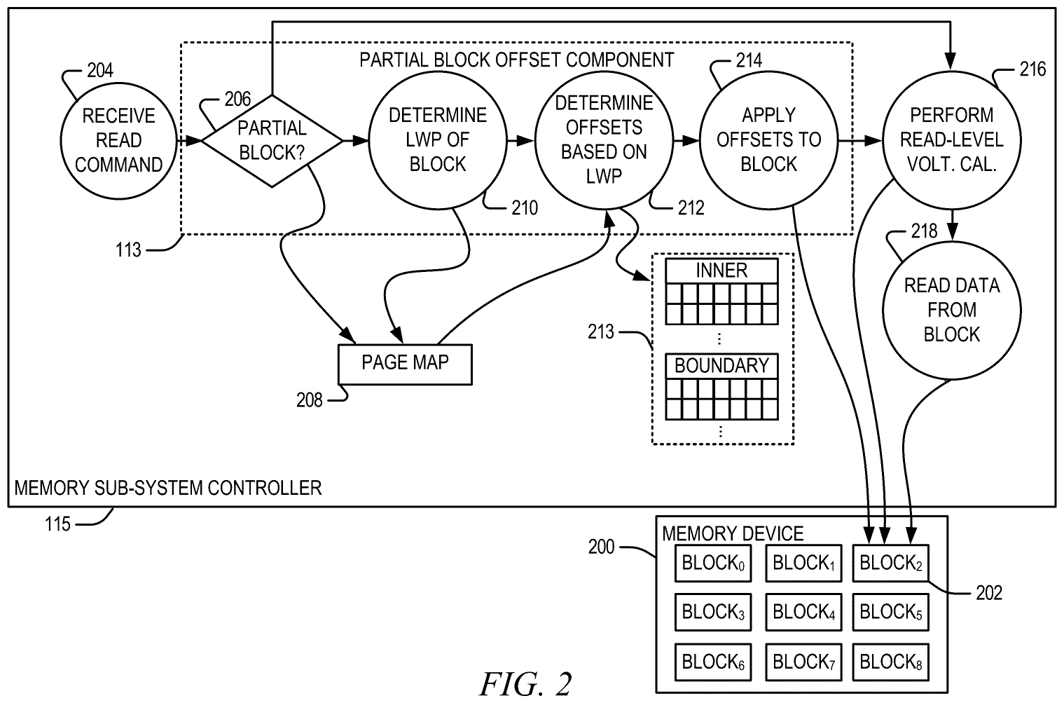

FIG. 2 is a data flow diagram illustrating interactions between components in the memory sub-system in performing a method for applying read-level voltage offsets in partial blocks, in accordance with some embodiments of the present disclosure. In the example illustrated in FIG. 2, a memory device 200 is an example memory device 130 in the example form of a NAND memory device.

The memory device 200 includes multiple NAND dies. Each die may include one or more planes and each plane includes multiple blocks such as block₀-block₈ illustrated in FIG. 2. Each block includes a two or three dimensional array that includes pages (rows) and strings (columns). A string includes a plurality of memory cells connected in series. Each memory cell is used to represent one or more bit values. For example, a single NAND flash cell includes a transistor that stores an electric charge on a memory layer that is isolated by oxide insulating layers above and below. Within each cell, data is stored as the Vt of the transistor. SLC NAND, for example, can store one bit per cell. Other types of memory cells, such as MLCs, TLCs, QLCs, and penta-level cells (PLCs), can store multiple bits per cell. In this example, the NAND memory includes an SLC portion that includes multiple SLCs and a QLC portion that includes multiple QLCs.

As noted above, each NAND cell stores data in the form of the Vt of the transistor. The range of Vts of a memory cell can be divided into a number of regions based on the number of bits stored by the cell where each region corresponds to a value that can be represented by the cell. More specifically, each region corresponds to a read voltage level (also referred to simply as “read level”) and each read voltage level decodes into a multi-bit value. For example, a TLC NAND flash cell can be at one of eight read levels (L0, L1, L2, L3, L4, L5, L6, or L7) and each read level decodes into a 3-bit value that is stored in the flash cell (e.g., 111, 110, 100, 000, 010, 011, 001, and 101).

At operation 204, the memory sub-system controller 115 receives a command (e.g., from host system 120) to read data stored in a block 202 of the memory device 200. At operation 206, the partial block offset component 113 determines whether the block 202 is a partial block based on whether the block 202 has any unprogrammed pages. As noted above, a block with no unprogrammed pages is considered a full block, while a block with at least one programmed page and at least one unprogrammed page is a partial block. The partial block offset component 113 can determine whether the block 202 is a partial block based on a stored page map 208 used to track a programmed status of each page in the block. That is, the page map identifies programmed and unprogrammed pages in the block.

If the block 202 has at least one unprogrammed page, the partial block offset component 113 determines initial read-level voltage offsets for the block (also referred to as “first read-level voltage offsets” below) before performing the read-level voltage calibration process. In doing so, the partial block offset component 113 determines, at operation 210, the LWP in the block 202 using the page map 208.

At operation 212, the partial block offset component 113 uses a partial block offset table 213 to determine a first set of read-level voltage offsets for the block 202 based on the LWP. The partial block offset table 213 comprises a mapping between word line numbers and read-level voltage offsets for partial blocks. More specifically, each row of the partial block offset table corresponds to one or more word line numbers (e.g., a range of word line numbers) and each row includes a set of read level voltage offsets. The set of read level voltage offsets in each row includes a read level voltage offset for each read level. Table 1, shown below, is an example partial block offset table.

TABLE 1

| | | | | | | | |
|---|---|---|---|---|---|---|---|
| Last WL | R1 | R2 | R3 | R4 | R5 | R6 | R7 |

Inner Word Line

| | | | | | | | |
|---|---|---|---|---|---|---|---|
| <57 | −13 | −11 | −9 | −8 | −5 | −3 | 0 |
| [51, 91) | −9 | −7 | −5 | −4 | −2 | 0 | 0 |
| [91, 126) | −8 | −4 | −3 | −4 | −3 | −1 | 0 |
| [126, 180) | −5 | −3 | −2 | −2 | −1 | 0 | 0 |
| [180, 216) | −3 | −3 | −3 | −2 | 0 | 0 | 0 |
| [216, 228) | −2 | −2 | −2 | −2 | 0 | 0 | 0 |
| >==228 | 0 | 0 | 0 | 0 | 0 | 0 | 0 |

Boundary Word Line

| | | | | | | | |
|---|---|---|---|---|---|---|---|
| <57 | −23 | −17 | −13 | −10 | −6 | −2 | 0 |
| [51, 91) | −19 | −15 | −11 | −9 | −6 | −3 | 0 |
| [91, 126) | −18 | −12 | −9 | −9 | −7 | −4 | 0 |
| [126, 180) | −15 | −11 | −8 | −7 | −5 | −3 | 0 |
| [180, 216) | −13 | −11 | −9 | −7 | −5 | −3 | 0 |
| [216, 228) | −11 | −8 | −6 | −4 | −2 | −1 | 0 |
| >==228 | −10 | −8 | −6 | −5 | −4 | −3 | 0 |

As illustrated by the example in Table 1, the partial block offset table 213 is further organized by word line type. Word line types include boundary word line and inner word line. Hence, the partial block offset table 213 specifies different read-level voltage offsets for inner word lines and boundary word lines. That is, for a first word line number at a first read level, the partial block offset table 213 specifies a first read-level voltage offset for an inner word line and a second read-level voltage offset for a boundary word line. Boundary word lines often exhibit different characteristics compared to the inner word lines, such as a greater shift in Vt. Hence, the read-level voltage offset for given read level of a given word line when it is a boundary word line is higher than the read-level voltage offset at the read level for the word line when it is an inner word line.

To identify the first set of voltage read-level offsets for the block 202 from the partial block offset table 213, the partial block offset component 113 determines the word line type based on the LWP in the block 202. The partial block offset component 113 identifies the LWP for the block from the page map and determines whether word lines of the LWP correspond to inner word lines or boundary word lines based on the identified LWP in the page map.

At operation 214, the partial block offset component 113 applies the first set of read-level voltage offsets to memory cells in the block 202. In an example, partial block offset component 113 applies the first set of voltage offsets to memory cells in the block 202 by issuing one or more commands to the memory device 200.

As shown, the operation 216 is performed either after applying the first set of read-level voltage offsets or without application of the first set of read-level offsets if the block is determined to be a full block (i.e., it has no unprogrammed pages). At operation 216, the controller 115 (or a component thereof) performs the read-level voltage calibration process with the first set of read-level voltage offsets applied to the memory cells of the block. In general, the read-level voltage calibration process includes determining a second set of read-level voltage offsets for the block. For some example implementations, the read-level voltage calibration process is based on or includes DCFB sensing. Consistent with these example implementations, the second set of read-level voltage offsets for the block are determined based on a number of failing bits read from the block with the first set of read-level voltage applied to the one or more word lines.

In an example, the controller 115 performs a first read operation at the block with the first set of read-level voltage offsets applied to memory cells of the block, and the controller 115 determines the number of failing bits read from the block based on the first read operation (e.g., based on data read from a dedicated portion of the block such as a Count Fail byte (CFByte). The controller 115 determines the second set of read-level voltage offsets for the block based on the number of failing bits read from the block using a stored look-up table (e.g., a DCFB calibration table). The stored look-up table specifies a set of read-level voltage offsets for each of multiple bins. The controller 115 categorizes the block into one of multiple bins based on the number of failing bits in the block and determines read-level voltage offsets for the block from the look-up table using the bin into which the block is categorized.

At operation 218, the controller 115 performs a second read operation on the block with the second set of read-level voltage offsets applied to read the data from the block. The processing device provides the data response to the read command (e.g., to the host system 120).

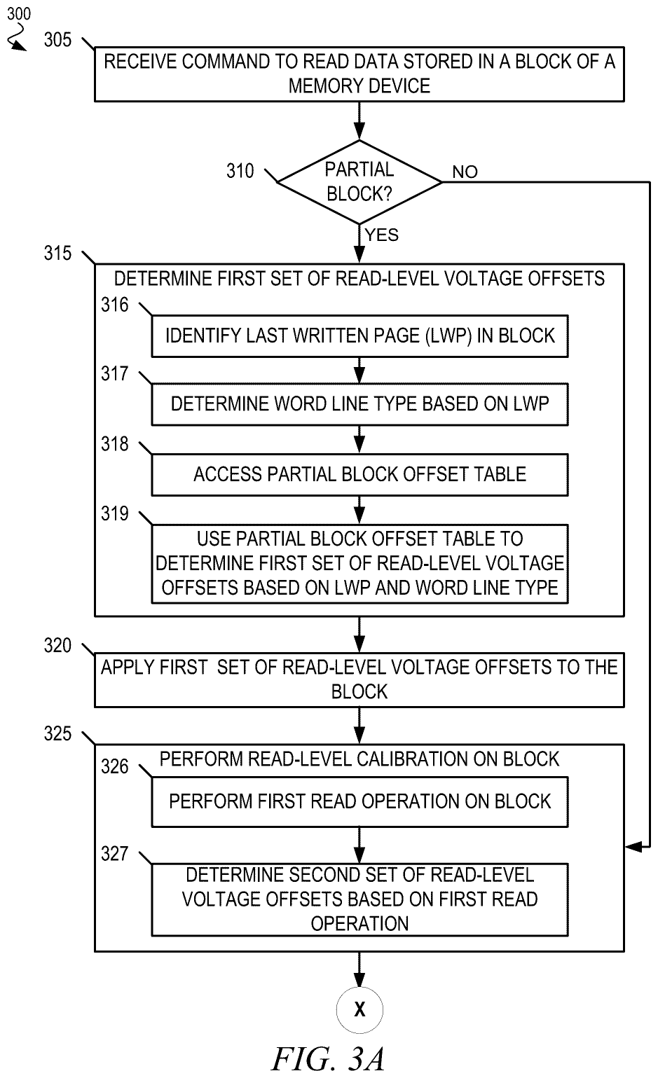

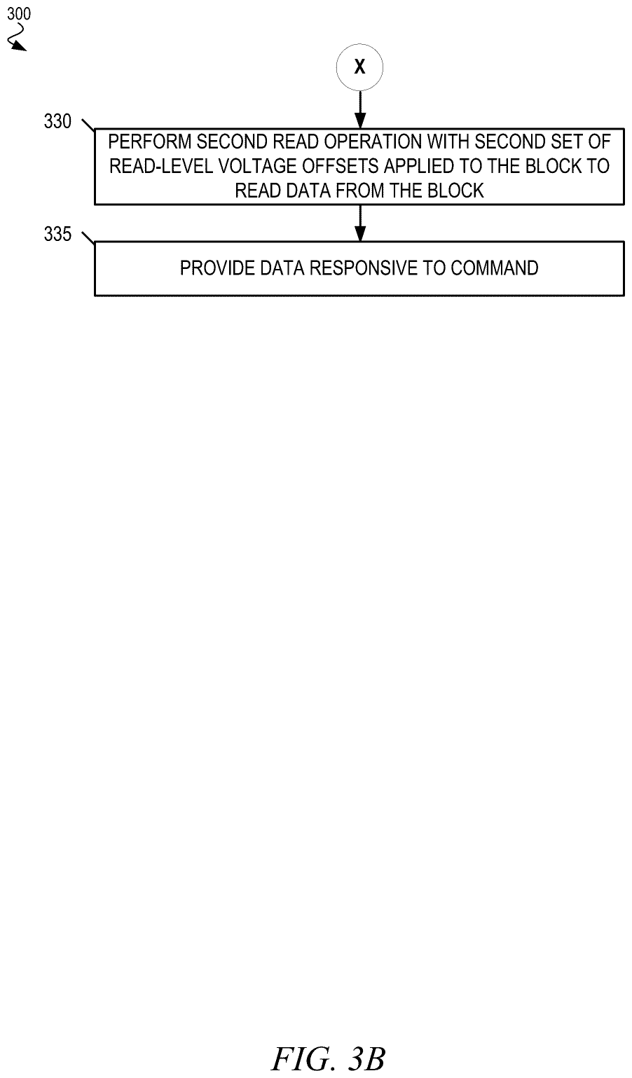

FIGS. 3A and 3B are flow diagrams illustrating an example method 300 for performing a method for applying read-level voltage offsets in partial blocks, in accordance with some embodiments of the present disclosure. The method 300 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some embodiments, the method 300 is performed by the Partial block offset component 113 of FIG. 1. Although processes are shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

With reference to FIG. 3A, at operation 305, the processing device receives a command to read data stored in a block of a memory device. The processing device, at operation 310, determines whether the block is a partial block. The processing device determines whether the block is a partial block based on whether the block has any unprogrammed pages in addition to at least one programmed page. If the block has no unprogrammed pages, the processing device determines the block is a full block and the method 300 proceeds to operation 325, discussed below.

If the block has at least one unprogrammed page, the processing device determines the block is a partial block. Based on the block being a partial block, the processing device, at operation 315, determines a first set of read-level voltage offsets for the block.

As shown, the operation 315 includes operations 316, 317, 318, and 319, in some example implementations. At operation 316, the processing device identifies a LWP in the block. To identify the LWP in the block, the processing device accesses a page map used to track a programmed status of each page in the block. That is, the page map identifies programmed and unprogrammed pages in the block. The processing device identifies the LWP of the block from the page map.

At operation 317, the processing device determines a word line type based on the LWP. Determining the word line type includes determining whether the LWP comprises an inner word line or a boundary word line. An inner word line refers to the word lines within a block that are not the last written word lines. That is, these are the word lines that are programmed after the initial programming but before the block reaches its full capacity and they are considered ‘inner’ because they are surrounded by other programmed word lines within the block. A boundary word line, on the other hand, is the last programmed word line in a partial block. A boundary word line represents the boundary between the programmed and unprogrammed areas of the block. The processing device determines the word line type based on the page map.

The processing device accesses a partial block offset table at operation 318. The partial block offset table comprises a mapping between word line numbers and read-level voltage offsets for partial blocks.

The processing device, at operation 319, uses the partial block offset table to determine a first set of read-level voltage offsets for the block based on the one or more word lines numbers corresponding to the LWP and the word line type.

At operation 320, the processing device applies the first set of read-level voltage offsets to memory cells in the block. In an example, the processing device applies the first set of voltage offsets to the one or more word lines by issuing one or more commands to the memory device.

At operation 325, the processing device performs a read-level voltage calibration process that includes determining a second set of read-level voltage offsets for the block based on a number of failing bits read from the block with the first set of read-level voltage applied.

In an example, the read-level voltage calibration process comprises a DCFB sensing method and the operation 320 includes operations 326 and 327. At operation 326, the processing device performs a first read operation at the block with the first set of read-level voltage offsets applied to memory cells of the block, and the processing device determines the number of failing bits read from the block based on the first read operation. In a first example, the processing device may read data from the block and count the number of failing bits. In a second example, the processing device may read data from a dedicated portion of the block (e.g., a CFByte) to determine a number of failing bits.

At operation 327, the processing device determines the second set of read-level voltage offsets for the block based on the number of failing bits read from the block. In an example, the processing device determines the second set of read-level voltage offsets using a stored look-up table (e.g., a DCFB calibration table) that specifies a set of read-level voltage offsets for each of multiple bins. More specifically, the processing device categorizes the block into one of multiple bins based on the number of failing bits in the block, and the processing device determines read-level voltage offsets for the block from the look-up table using the bin into which the block is categorized.

With reference to FIG. 3B, at operation 330, the processing device performs a second read operation on the block with the second set of read-level voltage offsets applied to read the data from the block. The processing device provides the data response to the read command, at operation 335.

Example 1. A memory sub-system comprising: a memory device; and a processing device, operatively coupled with the memory device to perform operations comprising: receiving a command to read data stored in a block of the memory device; determining the block is a partial block based on the block having one or more unprogrammed pages; based on the block being a partial block, accessing a partial block offset table comprising a mapping between word line numbers and read-level voltage offsets for partial blocks; identifying a last written page in the block; determining a word line type based on the last written page; determining, from the partial block offset table, a set of first read-level voltage offsets for the block based on one or more word line numbers associated with the last written page and the word line type; and applying the set of first read-level voltage offsets to the block as part of performing a read-level voltage calibration process that includes determining a second set of read-level voltage offsets for the block based on a number of failing bits read from the block.

Example 2. The memory sub-system of Example 1, wherein the operations comprise: performing a first read operation at the block with the first set of read-level voltage offsets applied to the block; determining the number of failing bits read from the block based on the first read operation; determining the second set of read-level voltage offsets based on the number of failing bits read from the block; and performing a second read operation with the second set of read-level voltage offsets applied to read the data from the block.

Example 3. The memory sub-system of any one of Examples 1 or 2, wherein the read-level voltage calibration process comprises performing digital count fail byte (DCFB) sensing.

Example 4. The memory sub-system of any one of Examples 1-3, wherein determining the word line type comprises determining whether the last written page corresponds to an inner word line or a boundary word line.

Example 5. The memory sub-system of any one of Examples 1-4, wherein determining whether the last written page corresponds to an inner word line or a boundary word line is based on a page map, the page map identifying pages in the block that have been programmed.

Example 6. The memory sub-system of any one of Examples 1-5, wherein the partial block offset table specifies different read-level voltage offsets for different word line types.

Example 7. The memory sub-system of any one of Examples 1-6, wherein, for a first word line number at a first read level, the partial block offset table specifies a first read-level voltage offset for an inner word line and a second read-level voltage offset for a boundary word line, wherein the second read-level voltage offset is higher than the first read-level voltage offset.

Example 8. The memory sub-system of any one of Examples 1-7, wherein determining the last written page comprises accessing a page map identifying pages in the block that have been programmed.

Example 9. The memory sub-system of any one of Examples 1-8, wherein each row of the partial block offset table corresponds to one or more word line numbers and each row includes a set of read level voltage offsets, the set of read level voltage offsets in each row including a read level voltage offset for each read level.

Example 10. A method comprising: receiving a command to read data stored in a block of a memory device; based on the block being a partial block, accessing a partial block offset table comprising a mapping between word line numbers and read-level voltage offsets for partial blocks; identifying a last written page in the block; determining a word line type based on the last written page; determining, from the partial block offset table, a set of first read-level voltage offsets for the block based on one or more word line numbers associated with the last written page and the word line type; and applying the set of first read-level voltage offsets to memory cells of the block as part of performing a read-level voltage calibration process that includes determining a second set of read-level voltage offsets for the block based on a number of failing bits read from the block.

Example 11. The method of Example 10, comprising determining the block is a partial block based on the block having one or more unprogrammed pages.

Example 12. The method of any one of Examples 10 or 11, comprising: performing a first read operation at the block with the first set of read-level voltage offsets applied; determining the number of failing bits read from the block based on the first read operation; determining the second set of read-level voltage offsets based on the number of failing bits read from the block; and performing a second read operation with the second set of read-level voltage offsets applied to read the data from the block.

Example 13. The method of any one of Examples 10-12, wherein the read-level voltage calibration process comprises performing digital count fail byte (DCFB) sensing.

Example 14. The method of any one of Examples 10-13, wherein determining the word line type comprises determining whether the last written page corresponds to an inner word line or a boundary word line.

Example 15. The method of any one of Examples 10-14, wherein determining whether the last written page corresponds to an inner word line or a boundary word line is based on a page map, the page map identifying pages in the block that have been programmed.

Example 16. The method of any one of Examples 10-15, wherein the partial block offset table specifies different read-level voltage offsets for different word line types.

Example 17. The method of any one of Examples 10-16, wherein, for a first word line number at a first read level, the partial block offset table specifies a first read-level voltage offset for an inner word line and a second read-level voltage offset for a boundary word line, wherein the second read-level voltage offset is higher than the first read-level voltage offset.

Example 18. The method of any one of Examples 10-17, wherein determining the last written page comprises accessing a page map identifying pages in the block that have been programmed.

Example 19. The method of any one of Examples 10-18, wherein each row of the partial block offset table corresponds to one or more word line numbers and each row includes a set of read level voltage offsets, the set of read level voltage offsets in each row including a read level voltage offset for each read level.

Example 20. A computer-readable storage medium comprising instructions that, when executed by a processing device, configure the processing device to perform operations comprising: receiving a command to read data stored in a block of a memory device; determining the block has one or more unprogrammed pages; based on determining the block has one or more unprogrammed pages, accessing a partial block offset table comprising a mapping between word line numbers and read-level voltage offsets for partial blocks; determining a word line type based on a last written page in the block; determining, from the partial block offset table, a set of first read-level voltage offsets for the block based on one or more word line numbers associated with the last written page and the word line type; and applying the set of first read-level voltage offsets to the block as part of performing a read-level voltage calibration process that includes determining a second set of read-level voltage offsets for the block based on a number of failing bits read from the block.

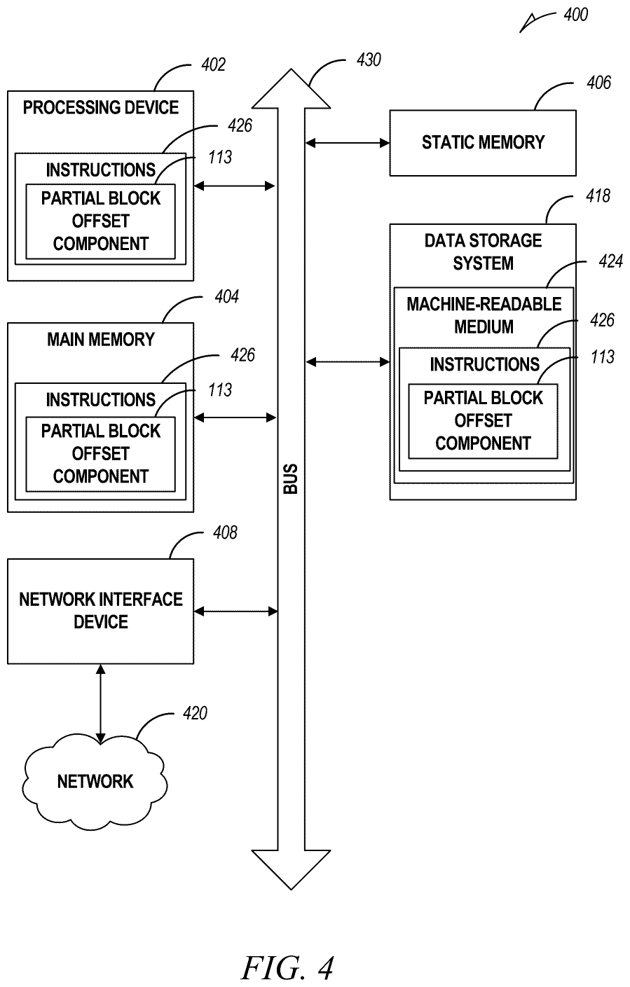

FIG. 4 illustrates an example machine in the form of a computer system within which a set of instructions can be executed for causing the machine to perform any one or more of the methodologies discussed herein. FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the Partial block offset component 113 of FIG. 1). In alternative embodiments, the machine can be connected (e.g., networked) to other machines in a local area network (LAN), an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., ROM, flash memory, DRAM such as SDRAM or RDRAM, etc.), a static memory 406 (e.g., flash memory, static random access memory (SRAM), etc.), and a data storage system 418, which communicate with each other via a bus 430.

Processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 402 can also be one or more special-purpose processing devices such as an ASIC, a FPGA, a digital signal processor (DSP), network processor, or the like. The processing device 402 is configured to execute instructions 426 for performing the operations and steps discussed herein. The computer system 400 can further include a network interface device 408 to communicate over a network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory sub-system 110 of FIG. 1.

In one embodiment, the instructions 426 include instructions to implement functionality corresponding to a partial block offset component (e.g., the Partial block offset component 113 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a ROM, RAM, magnetic disk storage media, optical storage media, flash memory components, etc.

In the foregoing specification, embodiments of the disclosure have been described with reference to specific example embodiments thereof. It will be evident that various modifications can be made thereto without departing from the broader scope of embodiments of the disclosure as set forth in the following claims. The specification and drawings are, accordingly, to be regarded in an illustrative sense rather than a restrictive sense.

What is claimed is:

1. A memory sub-system comprising:
a memory device; and
a processing device, operatively coupled with the memory device to perform operations comprising:
receiving a command to read data stored in a block of the memory device;
determining the block is a partial block based on the block having one or more unprogrammed pages;
based on the block being a partial block, accessing a partial block offset table comprising a mapping between word line numbers and read-level voltage offsets for partial blocks;
identifying a last written page in the block;
determining a word line type based on the last written page;
determining, from the partial block offset table, a set of first read-level voltage offsets for the block based on one or more word line numbers associated with the last written page and the word line type; and
applying the set of first read-level voltage offsets to the block as part of performing a read-level voltage calibration process that includes determining a second set of read-level voltage offsets for the block based on a number of failing bits read from the block.

2. The memory sub-system of claim 1, wherein the operations comprise:
performing a first read operation at the block with the first set of read-level voltage offsets applied to the block;
determining the number of failing bits read from the block based on the first read operation;
determining the second set of read-level voltage offsets based on the number of failing bits read from the block; and
performing a second read operation with the second set of read-level voltage offsets applied to read the data from the block.

3. The memory sub-system of claim 1, wherein the read-level voltage calibration process comprises performing digital count fail byte (DCFB) sensing.

4. The memory sub-system of claim 1, wherein determining the word line type comprises determining whether the last written page corresponds to an inner word line or a boundary word line.

5. The memory sub-system of claim 4, wherein determining whether the last written page corresponds to an inner word line or a boundary word line is based on a page map, the page map identifying pages in the block that have been programmed.

6. The memory sub-system of claim 3, wherein the partial block offset table specifies different read-level voltage offsets for different word line types.

7. The memory sub-system of claim 3, wherein, for a first word line number at a first read level, the partial block offset table specifies a first read-level voltage offset for an inner word line and a second read-level voltage offset for a boundary word line, wherein the second read-level voltage offset is higher than the first read-level voltage offset.

8. The memory sub-system of claim 1, wherein determining the last written page comprises accessing a page map identifying pages in the block that have been programmed.

9. The memory sub-system of claim 1, wherein each row of the partial block offset table corresponds to one or more word line numbers and each row includes a set of read level voltage offsets, the set of read level voltage offsets in each row including a read level voltage offset for each read level.

10. A method comprising:
receiving a command to read data stored in a block of a memory device;
based on the block being a partial block, accessing a partial block offset table comprising a mapping between word line numbers and read-level voltage offsets for partial blocks;
identifying a last written page in the block;
determining a word line type based on the last written page;
determining, from the partial block offset table, a set of first read-level voltage offsets for the block based on one or more word line numbers associated with the last written page and the word line type; and
applying the set of first read-level voltage offsets to memory cells of the block as part of performing a read-level voltage calibration process that includes determining a second set of read-level voltage offsets for the block based on a number of failing bits read from the block.

11. The method of claim 10, comprising determining the block is a partial block based on the block having one or more unprogrammed pages.

12. The method of claim 10, comprising:
performing a first read operation at the block with the first set of read-level voltage offsets applied;
determining the number of failing bits read from the block based on the first read operation;
determining the second set of read-level voltage offsets based on the number of failing bits read from the block; and
performing a second read operation with the second set of read-level voltage offsets applied to read the data from the block.

13. The method of claim 10, wherein the read-level voltage calibration process comprises performing digital count fail byte (DCFB) sensing.

14. The method of claim 10, wherein determining the word line type comprises determining whether the last written page corresponds to an inner word line or a boundary word line.

15. The method of claim 14, wherein determining whether the last written page corresponds to an inner word line or a boundary word line is based on a page map, the page map identifying pages in the block that have been programmed.

16. The method of claim 14, wherein the partial block offset table specifies different read-level voltage offsets for different word line types.

17. The method of claim 14, wherein, for a first word line number at a first read level, the partial block offset table specifies a first read-level voltage offset for an inner word line and a second read-level voltage offset for a boundary word line, wherein the second read-level voltage offset is higher than the first read-level voltage offset.

18. The method of claim 10, wherein determining the last written page comprises accessing a page map identifying pages in the block that have been programmed.

19. The method of claim 10, wherein each row of the partial block offset table corresponds to one or more word line numbers and each row includes a set of read level voltage offsets, the set of read level voltage offsets in each row including a read level voltage offset for each read level.

20. A computer-readable storage medium comprising instructions that, when executed by a processing device, configure the processing device to perform operations comprising:
receiving a command to read data stored in a block of a memory device;
determining the block has one or more unprogrammed pages;
based on determining the block has one or more unprogrammed pages, accessing a partial block offset table comprising a mapping between word line numbers and read-level voltage offsets for partial blocks;
determining a word line type based on a last written page in the block;
determining, from the partial block offset table, a set of first read-level voltage offsets for the block based on one or more word line numbers associated with the last written page and the word line type; and
applying the set of first read-level voltage offsets to the block as part of performing a read-level voltage calibration process that includes determining a second set of read-level voltage offsets for the block based on a number of failing bits read from the block.
